(19) United States
(12) Patent Application Publication
(10) Pub. No.: US 2009/0226764 A1
(43) Pub. Date: Sep. 10, 2009

(54) Magnetic Recording Medium with Iridum-Manganese Based Intermediate Layer and Method of Manufacturing Same

(75) Inventors: Kumar Srinivasan, Singapore (SG); Rachid Sbiaa, Singapore (SG); S.N. Piramanayagam, Singapore (SG)

Correspondence Address: JACOBSON HOLMAN PLLC, 400 SEVENTH STREET N.W., SUITE 600, WASHINGTON, DC, 20004, US

(73) Assignee: AGENCY FOR SCIENCE, TECHNOLOGY & RESEARCH, Singapore (SG)

(21) Appl. No.: 12/398,574

(22) Filed: Apr. 17, 2009

Related U.S. Application Data
(60) Provisional application No. 61/064,451, filed on Mar. 6, 2008.

(51) Int. Cl. G11B 5/706; C23C 14/34

(52) U.S. Cl. 428/846; 204/192.15

(57) ABSTRACT

A magnetic recording medium and a method of making a magnetic recording medium are disclosed. The magnetic recording medium comprises an Iridium-Manganese based intermediate layer formed over a base structure and a magnetic recording layer formed over the Iridium-Manganese based intermediate layer.

### CROSS-REFERENCE TO RELATED APPLICATIONS

This application claims priority from U.S. Provisional Application Ser. No. 61/064,451 filed Mar. 6, 2008, which is incorporated by reference in its entirety.

### TECHNICAL FIELD

The present invention relates to magnetic recording media. In particular, it relates to the intermediate layer for perpendicular magnetic recording media for hard disk drives.

### BACKGROUND

Perpendicular magnetic recording media have been developed to provide higher recording density in data storage devices such as disk drives. A typical perpendicular magnetic recording medium includes a substrate and a magnetic recording layer formed over the substrate. CoCrPt-oxide has become the material of choice for modern perpendicular magnetic recording media, due to the excellent combination of properties such as strong crystallographic texture, large perpendicular magnetic anisotropy and coercivity, de-coupled and small grains, low noise etc. Areal densities as high as 1 Tbits/in² are expected to be attained using perpendicular recording media based on CoCrPt-Oxide.

In order to achieve the desired structural, microstructural and magnetic properties, the recording layer is typically grown on a Ruthenium (Ru) intermediate layer and a Tantalum (Ta) seed layer in that order. A soft magnetic underlayer (SUL) is also used underneath the Ta seed layer in double-layered perpendicular recording media. The Ru intermediate layer itself consists of two layers—one continuous Ru layer for promoting the perpendicular oriented crystalline growth, and another granular Ru layer for inducing the separation necessary for magnetic decoupling among the recording layer grains. On such Ru intermediate layers, the dispersion in the perpendicular texture of the CoCrPt-oxide recording layer is usually ˜4°, and the grain size is ˜6.5 nm. In order to achieve 600 Gbits/in² and higher areal densities, grain sizes have to be made smaller than 6 nm, keeping in mind the thermal stability of the recorded bits. At the same time, writability has to be improved. These issues are significant challenges.

Various attempts have been made to reduce the grain size in the magnetic recording layer, and to increase the recording density. In one approach, excessive oxygen is added during the deposition of the magnetic recording layer, in order to suppress the growth of the magnetic grains. However, this approach may also result in oxygen getting into the core of the magnetic grains, leading to deterioration in the properties and performance of the media. Another approach has been to reduce the grain size of the magnetic recording layer by tailoring the intermediate layer properties. In this scheme, the intermediate layer is sputtered in the presence of oxygen, which leads to reduced grain sizes of the intermediate layer, which is then replicated in the magnetic recording layer. With this method, it has been possible to obtain a mean grain pitch, i.e. center-to-center distance between the grains, of 6.4 nm. In a third approach, when a sub-monolayer (few A°) thick synthetic nucleation layer is used underneath either/both the intermediate layer or the magnetic recording layer, grain pitch below 6 nm could be obtained.

Efforts to improve the writability of the perpendicular magnetic recording media have usually focused on the magnetic recording layer itself. Schemes to reduce the writing field such as exchange-coupled composite media, and tilted magnetic recording media have been proposed. While the former scheme may become viable, the latter scheme faces practical difficulties related to production in sputtering systems. With regard to the few schemes that focus on the intermediate layer, a perpendicular magnetic recording layer structure incorporating a magnetic intermediate layer (MIL) was proposed that will help to pass the flux from the magnetic writing head. Another scheme has been proposed to alleviate the writability problem through a hybrid soft magnetic underlayer (Hy-SUL) design, wherein combinations of crystalline and amorphous SUL are used. However, even in the MIL and Hy-SUL schemes, a non-magnetic exchange-breaking layer is required between the MIL and the magnetic recording layer, and between the Hy-SUL and magnetic recording layer, which reduces the efficiency of the write fields.

Recently, an additional circumstance has arisen to add to the aforementioned challenges—Ru, being a precious metal whose availability on the earth's crust is limited, has seen a colossal rise in its price in recent times, increasing by almost 600%. In light of this price jump, the magnetic recording industry is urgently seeking an alternative material to replace Ru in the hard disk drive. Any such candidate material has to offer functional performance at least comparable, if not superior, to Ru.

### SUMMARY

In accordance with an aspect of the invention, a magnetic recording medium, comprises a base structure, an Iridium-Manganese based intermediate layer over the base structure, wherein the Iridium-Manganese based intermediate layer is primarily of the composition IrₓMn₁₋ₓ, where x, which is the atomic component of Iridium in the alloy, is between 15-40% and a magnetic recording layer over the Iridium-Manganese based intermediate layer, wherein the Iridium-Manganese based intermediate layer provides a template that determines a grain size and a grain size distribution of magnetic grains in the magnetic recording layer.

In embodiments, the Iridium-Manganese based intermediate layer is primarily of the composition IrₓMn₁₋ₓ, where x, which is the atomic component of Iridium in the alloy, is between 15-40%, along with additions of elements such as Cr, Pt, Pd, O, N etc., or combinations thereof, and provides a template that determines a grain size and a grain size distribution of magnetic grains in the magnetic recording layer. The Iridium-Manganese based intermediate layer can be in contact with the magnetic recording layer above it and a second intermediate layer such as Ru, Cu, Cr, Co, Fe, Ta, Ni, Al etc. or combinations thereof below it, and be sandwiched between the second intermediate layer and the magnetic recording layer. The grain size of the magnetic recording layer on the Iridium-Manganese based intermediate layer may have a mean of less than 6 nm, and the grain size distribution has a standard deviation of less than 15%. The magnetic recording media may be a disk that provides perpendicular magnetic recording for a disk drive.

In accordance with an aspect of the invention, a method of making a magnetic recording medium comprises providing a base structure, depositing an Iridium-Manganese based intermediate layer that is primarily of the composition IrₓMn₁₋ₓ, where x, which is the atomic component of Iridium in the alloy, is between 15-40% formed over the base structure, and sputtering a magnetic recording layer over the Iridium-Manganese based intermediate layer, wherein the Iridium-Manganese based intermediate layer provides a template that determines a grain size and a grain size distribution of magnetic grains in the magnetic recording layer.

In an embodiment of the invention a magnetic recording medium comprises a substrate, an amorphous soft magnetic underlayer over the substrate, a seedlayer, a first or lower intermediate layer over the seed layer, a crystalline soft magnetic underlayer over the first intermediate layer, and an Iridium-Manganese based intermediate layer over the crystalline soft magnetic underlayer, the Iridium-Manganese based intermediate layer is primarily of the composition IrₓMn₁₋ₓ, where x, which is the atomic component of Iridium in the alloy, is between 15-40%, which leads to Iridium-Manganese being in the antiferromagnetic state, and a magnetic recording layer over the Iridium-Manganese based intermediate layer, the antiferromagnetic Iridium-Manganese based intermediate layer helps to pin the magnetic domains in the crystalline soft underlayer on which it is deposited by means of exchange bias, and the Iridium-Manganese based intermediate layer provides a template that determines a grain size and a grain size distribution of the magnetic grains in the magnetic recording layer, and the magnetic recording layer provides perpendicular magnetic recording for a disk drive.

### BRIEF DESCRIPTION OF THE DRAWINGS

In order that embodiments of the invention may be fully and more clearly understood by way of non-limitative examples, the following description is taken in conjunction with the accompanying drawings in which like reference numerals designate similar or corresponding elements, regions and portions, and in which:

FIG. 1 illustrates the structure of a magnetic recording medium in accordance with an embodiment of the invention;

FIG. 2 illustrates the structure of a magnetic recording medium in accordance with an embodiment of the invention;

FIG. 3A illustrates the crystalline lattice structures of Cobalt, Ruthenium, and Iridium-Manganese in the atomic stoichiometric ratio of 1:3, and the lattice parameters of interest in the respective close packed planes, in accordance with an embodiment of the invention;

FIG. 3B illustrates that the magnetic susceptibility in antiferromagnetic Iridium-Manganese in the atomic stoichiometric ratio of 1:3, along the directions parallel to, and perpendicular to the cubic close packed (111) plane, are respectively zero and non-zero positive, in accordance with an embodiment of the invention;

FIG. 4 illustrates the change of the out-of-plane dispersion (Δθ₅₀) of the hexagonal close packed (0002) lattice plane of the Cobalt-based magnetic recording layer, and of the cubic close packed (111) lattice plane of the Iridium-Manganese based intermediate layer in accordance with an embodiment of the invention;

FIG. 5 illustrates the magnetic hysteresis loops, and the change in the coercivity (H_{c}), negative nucleation field (−Hₙ) and coercivity squareness (S*) of the Cobalt-based magnetic recording layer on Iridium-Manganese based intermediate layer in accordance an embodiment of the invention;

FIGS. 6A-6C illustrates the TEM micrographs of the Cobalt-based magnetic recording layer on Iridium-Manganese based intermediate layer which was prepared under sputtering conditions as noted, in accordance with an embodiment of the invention; and

FIG. 7 illustrates a graph of the grain size and grain size distribution curves of the Cobalt-based magnetic recording layer on Iridium-Manganese based intermediate layer which was prepared under sputtering conditions as noted, in accordance with an embodiment of the invention.

### DETAILED DESCRIPTION

The hexagonal Cobalt-based magnetic recording media typically is grown on Ruthenium or Ruthenium-based intermediate layers. The intermediate layer based on Ruthenium, which is either pure Ruthenium or an alloy of Ruthenium with elements such as Chromium, Cobalt, Copper etc., when in the hexagonal crystalline structure, provides a template for the heteroepitaxial growth of the hexagonal Cobalt-based magnetic recording layer. This is due to the close lattice matching of the hexagonal Ruthenium a-lattice parameter of 2.72 A° to the hexagonal Cobalt a-lattice parameter of 2.52 A°. In addition to providing a template for heteroepitaxial growth, the intermediate layer based on Ruthenium also serves to control the granular isolation, the grain size and grain size distribution of the Cobalt-based magnetic recording layer. In order to fulfill the above mentioned roles, the intermediate layer based on Ruthenium itself usually consists of two layers—a first layer for inducing the heteroepitaxial growth, and a second layer for inducing the well-isolated, columnar growth of the Cobalt-based magnetic recording layer. On such Ruthenium-based intermediate layers, the total thickness of which is about 15 nm, the Cobalt-based magnetic recording layer is polycrystalline with the perpendicular hexagonal (0002) texture holding a dispersion of about 4°, an average grain size usually greater than 6 nm, and grain size distribution usually greater than 15%.

In an embodiment of this invention, an intermediate layer based on Iridium-Manganese is used in place of at least one of the Ruthenium intermediate layers, namely the second intermediate layer that is used to induce granular isolation and control the grain size of the Cobalt-based magnetic recording layer. In the atomic composition of IrₓMn₁₋ₓ, where x is around 15-40%, Iridium-Manganese assumes the AuCu₃ prototype cubic crystalline lattice structure, which is a derivative of the face-centered cubic (fcc) lattice structure. In this crystal structure, Iridium-Manganese has a cubic lattice parameter of 3.778 A°, and its close-packed crystalline plane is the (111) crystallographic plane. In the (111) crystallographic plane, the distance between the near-neighbor atoms is 2.67 A°, which is closely matched with the value of 2.52 A° for the a-lattice parameter of hexagonal close packed (hcp) Cobalt-based recording layer. In comparison, the a-lattice parameter of hcp Ruthenium is 2.72 A°. Thus, Iridium-Manganese, when it assumes the AuCu₃ prototype crystal structure, provides better lattice matching and template for the hexagonal Cobalt-based recording layer compared to the hexagonal Ruthenium. Iridium-Manganese, when it assumes the AuCu₃ prototype crystal structure, is also a well known room temperature antiferromagnet with a bulk Neel temperature of 690 K (417° C.). The anti-parallel aligned magnetic spins lie in the (111) plane. This means that the magnetic susceptibility along the (111) plane is zero; however, it is non-zero and positive along the (111) plane normal i.e. the [111] direction.

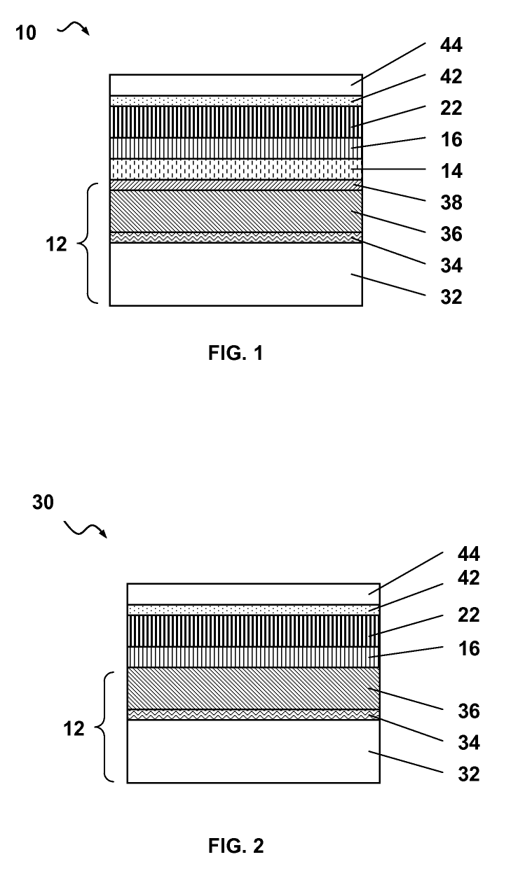

Referring to FIG. 1, a perpendicular magnetic recording medium 10 according to an embodiment of the invention includes a base structure 12, lower intermediate layer 14 disposed on the base structure 12, an upper intermediate layer 16 disposed on the lower intermediate layer 14, and a magnetic recording layer 22 disposed on the upper intermediate layer 16. Base structure 12 includes a substrate 32, and an adhesion layer 34, a soft magnetic layer 36 and a seed layer or a growth inducing layer 38 sequentially formed on a substrate 32. The lower intermediate layer 14 is deposited at a pressure of about 0.1-1 Pa. By depositing at such a pressure, lower intermediate layer 14 possesses a relatively narrow dispersion of crystallographic orientation of the grains. Thereafter, an upper intermediate layer 16 is deposited on the lower intermediate layer 14 at a pressure higher than the pressure used to deposit lower intermediate layer 14. The lower intermediate layer 14 helps to improve the crystallographic texture, and the upper intermediate layer 16, acting as a template for separating the densely packed grains, helps to obtain segregated grain structure in the recording layer to improve signal to noise ratio from the magnetic recording layer 22. In this embodiment, upper intermediate layer 16 is responsible for producing fine grains in the recording layer 22 and controls the grain size in the recording layer 22.

According to an embodiment of the invention, the upper intermediate layer 16 consists of an Iridium-Manganese alloy primarily of the composition IrₓMn₁₋ₓ, where x, which is the atomic component of Iridium in the alloy, is between 15-40%. Additional element and/or elements may be added to the Iridium-Manganese alloy, and included in the upper intermediate layer 16. For example, additional elements may be metals such as Cr, Ti, Ta, Pt, Pd, Ru, Rh, Re, Fe, Co, Ni, Zr, Ag, Au, In, Cu, Al, Mo, Nb, Mg and the like, and gasses such as hydrogen, nitrogen, oxygen, and the like. The Iridium in the Iridium-Manganese alloy may also be replaced by one or more of the elements such as Pt, Pd, Cr Fe, Ni, Co, Ru, Rh and the like, with or without the inclusion of additional gases such as hydrogen, nitrogen, oxygen and the like. The Iridium-Manganese based upper intermediate layer 16 is deposited for a thickness ranging from 3-10 nm of material at high sputter pressures of about 1-10 Pa. The Iridium-Manganese based upper intermediate layer 16 is disposed on the lower intermediate layer 14, which may consist of materials or elements such as Ru, Cr, Cu, Co, Ti, Zr, Ag, Au, Al, Mg, Mn, Pt, Pd, Ta, Nb, Mo, Re and the like, or combinations of these elements. Upon formation of the upper intermediate layer 16 on the lower intermediate layer 14, subsequent deposition processes may be carried out in the deposition chamber, to form magnetic recording layer 22 on top of the upper intermediate layer 16.

The Iridium-Manganese based upper intermediate layer 16, through excellent lattice-matching with the Cobalt-based magnetic recording layer 22, provides a template for the heteroepitaxial growth of the magnetic recording layer 22. At the same time, the magnetic grains in layer 22 grow following the structure of grains in layer 16. Due to the high sputter pressure process used to deposit the Iridium-Manganese based upper intermediate layer 16, reduced grain sizes are obtained for the upper intermediate layer 16, which is subsequently replicated in the magnetic recording layer 22. From this process, magnetic recording layer having reduced grain size is successfully obtained. Additionally, in the antiferromagnetic state, the Iridium-Manganese based intermediate layer 16 possesses a non-zero positive magnetic susceptibility in the perpendicular out-of-plane direction, and thus may help to channel the flux from the writing head, which may help in improving the writability.

Referring to FIG. 2, a perpendicular magnetic recording medium 30 according to another embodiment of the invention includes a base structure 12, an Iridium-Manganese based intermediate layer 16 disposed on the base structure 12, and a magnetic recording layer 22. Base structure 12 includes a substrate 32, and an adhesion layer 34, a soft magnetic layer 36 sequentially formed on a substrate 32. In this embodiment, the soft magnetic layer 36 consists of a crystalline or a combination (hybrid) of amorphous and crystalline soft magnetic underlayers. The crystalline soft magnetic underlayer, or the crystalline component of the hybrid soft magnetic underlayer could have an hcp (0002) or fcc (111) texture or a derivative of these. Additional layers may be inserted below the crystalline soft magnetic underlayers to induce a fcc (111) or hcp (0002) texture in the crystalline soft magnetic underlayers. According to this embodiment, the Iridium-Manganese based intermediate layer 16 is disposed directly on the soft magnetic underlayer 36, which consists of a crystalline soft magnetic underlayer, or a hybrid soft magnetic underlayer, on the base structure 12. In the antiferromagnetic state, the Iridium-Manganese based intermediate layer 16 helps to pin the magnetic domains in the soft magnetic underlayer 36 by means of exchange bias. In this embodiment, the crystalline soft magnetic underlayer, or the crystalline component of the hybrid soft magnetic underlayer, provides the template for the crystallographic heteroepitaxial growth of the Iridium-Manganese based intermediate layer 16. The Iridium-Manganese based intermediate layer 16 provides the template for, and helps to obtain segregate grain structure in the magnetic recording layer 22. In the antiferromagnetic state, the Iridium-Manganese based intermediate layer 16 possesses a non-zero positive magnetic susceptibility in the perpendicular out-of-plane direction, and thus helps to channel the flux from the writing head, which helps in improving the writability.

Referring to FIG. 1, in another embodiment, the perpendicular magnetic recording medium 10 includes a base structure 12, which may consist of amorphous or crystalline or a combination of soft magnetic underlayers 36. The layer 14 disposed on the base structure 12, could be magnetic or non-magnetic layer with an hcp (0002) or fcc (111) texture or a derivative of these. According to this embodiment, the Iridium-Manganese based upper intermediate layer 16 is disposed on the lower intermediate layer 14, and a magnetic recording layer 22 could be disposed on the upper intermediate layer 16. Base structure 12 includes a substrate 32, and an adhesion layer 34, a soft magnetic layer 36 and a seed layer 38 sequentially formed on a substrate 32. The lower intermediate layer 14 helps to improve the crystallographic texture, and the Iridium-Manganese based upper intermediate layer 16, acting as a template for separating the densely packed grains, helps to obtain segregated grain structure in the recording layer to improve signal to noise ratio from the magnetic recording layer 22. If the lower intermediate layer 14 is made of a magnetic or metamagnetic layer, it also helps to direct the flux from the writing head, which helps in improving the writability. In the antiferromagnetic state, the Iridium-Manganese based intermediate layer 16 can help to pin the magnetic domains in the lower intermediate layer 14, if the lower intermediate layer 14 is magnetic. In the antiferromagnetic state, the Iridium-Manganese based intermediate layer 16 possesses a non-zero positive magnetic susceptibility in the perpendicular out-of-plane direction, and thus helps to channel the flux from the writing head, which helps in improving the writability.

In an embodiment, the soft magnetic layer 36, i.e. soft underlayers, may be a combination of one or several layers which may or may not necessarily be crystalline. The soft underlayers may be made of a material from one or more elements such as for example Fe, Co, Ni, B, Ta, Zr, Nb, Si, Ti, Ru, Cu, Pt, Pd, Cr, and the like. The soft underlayers may also be a combination of one or several layers which may or may not necessarily be antiferromagnetically coupled synthetically. The soft underlayers may be pinned by antiferromagnetic material such as for example IrMn, FeMn, NiO, IrMnCr, IrMnPt, PtMnCr, PtMn, and the like. When present, the growth inducing layer may consist of one or a mixture of, for example Ta, Cu, Cr, Ti, Ag, Au, and the like. When present, the lower intermediate layer may be formed from one or a mixture of elements such as, for example Cr, Co, Fe, Ni, Cu, Ru, Pd. Pt, and the like. The upper intermediate layer may be of an alloy of Iridium and Manganese primarily of the composition IrₓMn₁₋ₓ, where x, which is the atomic component of Iridium in the alloy, is between 15-40%, along with materials such as for example Cr, Ti, Ta, Pt, Pd, Ru, Rh, Re, Fe, Co, Ni, Zr, Ag, Au, In, Cu, Al, Mo, Nb, Mg, alloys thereof, and the like. The Iridium-Manganese based upper intermediate layer may be sputtered in the presence of a reactive gas such as oxygen, nitrogen, hydrogen, and the like. In forming the intermediate layers, the lower intermediate layer may be formed under lower sputter pressure parameters to obtain more narrowly-dispersed grains than in forming the upper intermediate layer to obtain smaller-sized grains.

In an embodiment, the recording layer 22 is an alloy of two or more elements such as for example Co, Cr, Pt, B, Ta, Pd, Sm, Fe, Ni and the like. The recording layer may have an oxide based grain boundary to separate the grains from each other. The oxide based grain boundary may be obtained from one or more elements such as for example Si, Cr, Ta, Ti, Al, Mg and the like. The recording layer may be coated with a protective layer or a cover layer 42 such as for example carbon, nitrogenated carbon, hydrogenated carbon, silicon nitride and the like to improve resistance to corrosion. The cover layer 42 includes combination of carbon, nitrogenated carbon, hydrogenated carbon, silicon nitride and the like to improve resistance to corrosion and lubrication affinity. The recording layer 22 and the protective layer 42 may be coated with a lubricant material 44 such as PFPE to improve wear resistance. Additionally, the magnetic recording media may be buffed or undergo other post-sputter treatments in order to achieve a smooth surface.

It will be appreciated that the base structure 12 shown in FIGS. 1-2 may comprise different configurations. For example, base structure may comprise a substrate 32. The base structure may or may not include an adhesion layer 34 and/or growth inducing layer 38.

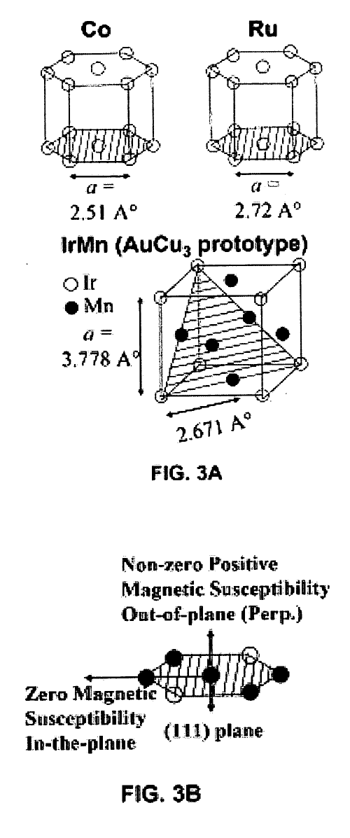

FIG. 3A shows the crystalline lattice structures of hexagonal Co, hexagonal Ru and the AuCu₃ prototype IrMn, and FIG. 3B shows the magnetic susceptibility of antiferromagnetic materials in general, and IrMn in particular, along the directions parallel to and perpendicular to the crystalline plane in which the magnetic spins are oriented. In FIG. 3A, the heteroepitaxy-inducing crystalline lattice parameters, such as the a-lattice parameter of Co, the a-lattice parameter of Ru, the a-lattice parameter of IrMn, and the distance between the near-neighbor atoms of IrMn along the (111) lattice plane are noted. When grown with the (111) crystalline texture perpendicular to the substrate, AuCu₃ prototype IrMn provides a better lattice matching with hexagonal Co than does hexagonal Ru, and thus can be a superior template for hexagonal Co to grow on. FIG. 3B illustrates that the anti-parallel aligned magnetic spins in the AuCu₃ prototype IrMn lie in the (111) crystalline plane; the magnetic susceptibility of antiferromagnetic materials is zero and positive respectively, along the direction parallel to and perpendicular to the plane of the magnetic spins. Thus, in the case of the AuCu₃ prototype IrMn, the magnetic susceptibility is zero and positive respectively, along the direction parallel to and perpendicular to the (111) crystalline plane. As a result, when grown with the (111) crystalline texture perpendicular to the substrate, AuCu₃ prototype IrMn can have a non-zero positive magnetic susceptibility perpendicular to the substrate, and help in passing the flux from the write head, which can help to improve the writability.

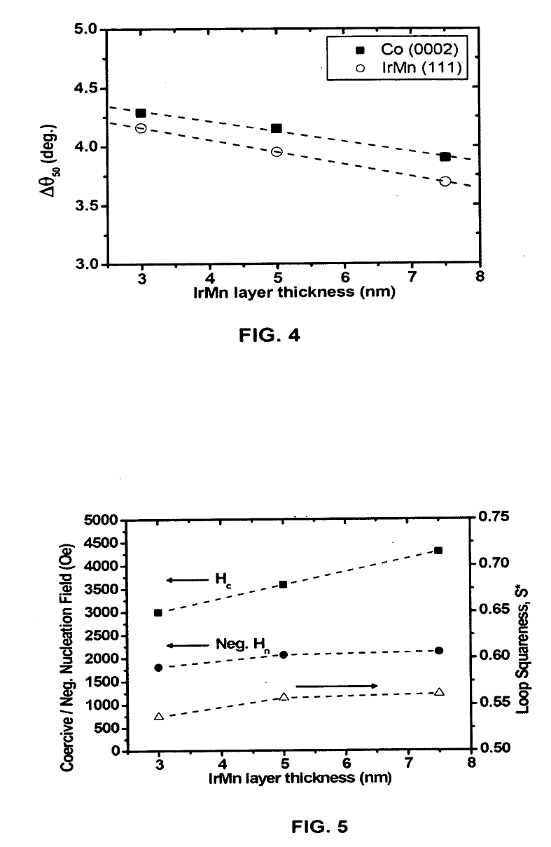

FIG. 4 illustrates the change in the perpendicular texture (Δθ₅₀) of the (111) crystalline plane of the AuCu₃ prototype IrMn upper intermediate layer 16, and of the (0002) crystalline plane of the Co-based magnetic recording layer 22, as a function of the thickness of the IrMn upper intermediate layer 16. In this case, the base structure 12 consisted of Al—Mg substrate 32, Ta adhesion layer 34, antiferromagnetically-coupled amorphous CoTaZr soft magnetic underlayer 36, and 5 nm thick Ta seed layer 38. The lower intermediate layer 14 consisted of 7.5 nm of hexagonal Ru, on which AuCu₃ prototype IrMn upper intermediate layer 16 of different thickness ranging from 3 nm to 7.5 nm was deposited at a high Argon sputter gas pressure of about 10 Pa. On the IrMn upper intermediate layer 16, CoCrPt—SiO₂ type magnetic recording layer of thickness 14 nm was deposited at total sputter gas pressure of about 9 Pa, with about 2.3% partial pressure of oxygen (pO₂) in Argon. It is clear that the Δθ₅₀ of the perpendicular texture of both the IrMn upper intermediate layer 16, and the magnetic recording layer 22 decreases as the thickness of the IrMn upper intermediate layer 16 increases. Δθ₅₀ values below 4° can be obtained for the magnetic recording layer 22 on the IrMn upper intermediate layer 16. This Δθ₅₀ value is comparable to what is usually obtained when the upper intermediate layer 16 consists of Ruthenium.

FIG. 5 illustrates the magnetic hysteresis loops obtained from magneto-optical Kerr effect (MOKE) measurements, and the change in the coercivity (Hc), negative nucleation field (−Hn), and the coercive squareness, of the Co-based magnetic recording layer 22, when sputter deposited on IrMn upper intermediate layer 16 of thickness ranging from 3 nm to 7.5 nm. As the thickness of the IrMn upper intermediate layer 16 increased, the Kerr hysteresis loop showed progressive shearing, which indicates enhanced exchange-decoupling of the magnetic grains of the magnetic recording layer 22. The coercivity increased with the increased thickness of the IrMn upper intermediate layer 16, whereas the negative nucleation field changed only slightly. This additionally indicates that the magnetic recording grains become progressively decoupled as the thickness of the IrMn upper intermediate layer 16 increased.

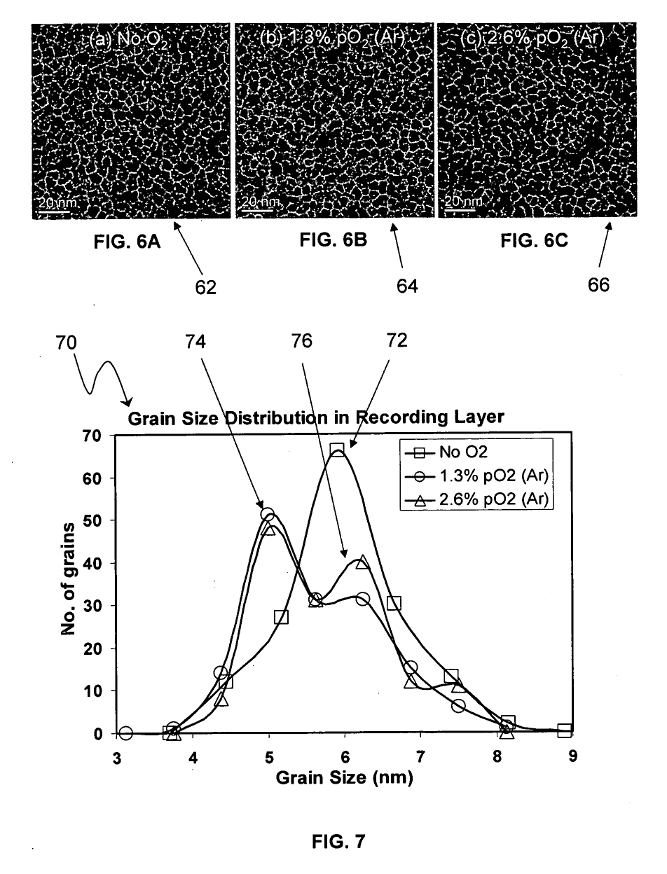

A comparison is shown in FIGS. 6A-6C between transmission electron microscope (TEM) images of the grains of the magnetic recording layer 22 grown on IrMn based upper intermediate layer 16. As discussed and shown in FIG. 1 in accordance with an embodiment of the invention, the magnetic recording layer 22 consisted of 14 nm thick CoCrPt—SiO₂ deposited at total sputter gas pressure of about 9 Pa, with about 2.3% partial pressure of oxygen (pO₂) in Argon disposed on 7.5 nm thick IrMn based upper intermediate layer 16. The IrMn based upper intermediate layer 16 was deposited at high Argon sputter gas pressure of about 10 Pa, without O₂ (FIG. 6A), and with O₂ at different partial pressures (FIGS. 6B and 6C) present in the sputter gas mixture, as indicated. The IrMn based upper intermediate layer 16 was deposited on 5 nm thick Ru lower intermediate layer and 5 nm thick Ta seed layer in that order. It is clear that the images of all three samples 62, 64 and 66 show well-separated grains in the magnetic recording layer.

The grain size in the magnetic recording layer 22, the TEM images of which are shown in FIGS. 6A-6C, was estimated by measuring the distance between the grain centers. FIG. 7 is a graph 70 showing grain size and grain size distribution curves 72, 74, 76 of the magnetic recording layer 22 according to embodiments of the present invention. Curve 72 is for magnetic recording layer 22 on IrMn upper intermediate layer 16 deposited without O₂ in the Argon sputter gas, curve 74 is for magnetic recording layer 22 on IrMn upper intermediate layer 16 deposited at 1.3% pO₂ in the Argon sputter gas mixture, and curve 76 is for magnetic recording layer 22 on IrMn upper intermediate layer 16 deposited at 2.6% pO₂ in the Argon sputter gas mixture. The mean grain size in the case of curve 72 is 6.0 nm with a distribution of ±0.8 nm or 13.3%, in the case of curve 74 is 5.8 nm with a distribution of ±0.8 nm or 13.8%, and in the case of curve 76 is 5.6 nm with a distribution of ±0.8 nm or 14.3%. Thus small, uniform and sub-6 nm grains of the magnetic recording layer 22 could be obtained on the IrMn based upper intermediate layer 16. These grain sizes are smaller than reported grain sizes for the magnetic recording layer on Ru or Ru-based upper intermediate layer, and thus clearly indicate the effectiveness of the IrMn based upper intermediate layer in inducing small grain sizes and distributions required for high-density recording media.

The use of Iridium-Manganese based materials as an intermediate layer for perpendicular magnetic recording media is demonstrated. Empirical data obtained with the embodiments of the invention have shown that grain sizes 6.0 nm and below with standard deviations of 14% or less could be obtained for the magnetic recording layer on Iridium-Manganese based intermediate layer. The dispersion in the perpendicular texture of the magnetic recording layer on Iridium-Manganese based intermediate layer was only 4° or smaller, and the magnetic coercivity greater than 4000 Oe along with exchange-decoupled grains could also be obtained. In the antiferromagnetic state, Iridium-Manganese which has non-zero positive magnetic susceptibility can also contribute towards passing the magnetic flux from the write head, and help to improve writability of the media. The embodiments of the invention can help to solve major problems for high-density perpendicular magnetic recording media.

It will be appreciated that the technology and application of embodiments of the invention may be applied to granular perpendicular magnetic recording media prepared by sputtering techniques, as well as discrete track perpendicular magnetic recording media prepared by patterning techniques such as nanoimprint lithography.

While embodiments of the invention have been described and illustrated, it will be understood by those skilled in the technology concerned that many variations or modifications in details of design or construction may be made without departing from the present invention.

1. A magnetic recording medium, comprising:
a base structure;
an Iridium-Manganese based intermediate layer over the base structure, wherein the Iridium-Manganese based intermediate layer is primarily IrₓMn₁₋ₓ, wherein x, which is the atomic component of Iridium in the alloy, is between 15-40%; and
a magnetic recording layer over the Iridium-Manganese based intermediate layer.

2. The magnetic recording medium according to claim 1, wherein the base structure comprises a substrate.

3. The magnetic recording medium according to claim 1, wherein the base structure comprises a substrate with an adhesion layer over the substrate.

4. The magnetic recording medium according to claim 1, wherein the base structure comprises a substrate, an adhesion layer over the substrate and a soft magnetic underlayer.

5. The magnetic recording medium according to claim 4, wherein the base structure further comprises a growth inducing layer over the soft magnetic underlayer.

6. The magnetic recording medium according to claim 4, wherein the soft magnetic underlayer comprises a combination of one or several crystalline or non-crystalline layers comprising of one or more elements selected from the group consisting of Fe, Co, Ni, B, Ta, Zr, Nb, Si, Ti, Ru, Cu, Pt, Pd and Cr.

7. The magnetic recording medium according to claim 4, wherein the soft magnetic underlayer comprises a combination of one or several layers antiferromagnetically coupled synthetically and pinned by one or more antiferromagnetic materials selected from the group consisting of IrMn, FeMn, NiO, IrMnCr, IrMnPt, PtMnCr and PtMn.

8. The magnetic recording medium according to claim 5, wherein the growth inducing layer is selected from the group consisting of Ta, W, Ti, In, Ag, Cu and alloys thereof.

9. The magnetic recording medium according to claim 1, further comprising a lower intermediate layer, wherein the Iridium-Manganese based intermediate layer is an upper intermediate layer that is spaced from the base structure, and the lower intermediate layer is sandwiched between the Iridium-Manganese based upper intermediate layer and the base structure.

10. The magnetic recording medium according to claim 9, wherein the lower intermediate layer is ruthenium.

11. The magnetic recording medium according to claim 9, wherein the lower intermediate layer is selected from the group consisting of Ru, Cr, Cu, Co, Ti, Zr, Ag, Au, Al, Mg, Mn, Pt, Pd, Ta, Nb, Mo, Re and alloys thereof.

12. The magnetic recording medium according to claim 9, wherein the Iridium-Manganese based upper intermediate layer is sputtered at a higher sputter gas pressure than the lower intermediate layer it is disposed on.

13. The magnetic recording medium according to claim 1, wherein at least one other intermediate layer is disposed between the Iridium-Manganese based intermediate layer and the magnetic recording layer for controlling the crystallographic and morphological properties of the magnetic recording layer.

14. The magnetic recording medium according to claim 1, wherein the Iridium-Manganese based intermediate layer comprises a material selected from the group consisting of Cr, Ti, Ta, Pt, Pd, Ru, Rh, Re, Fe, Co, Ni, Zr, Ag, Au, In, Cu, Al, Mo, Nb, Mg and alloys thereof.

15. The magnetic recording media according to claim 1, wherein the Iridium-Manganese based intermediate layer comprises a gas selected from the group consisting of hydrogen gas, nitrogen gas and oxygen gas.

16. The magnetic recording medium according to claim 1, further including a metal selected from the group consisting of Pt, Pd, Cr, Fe, Ni, Co, Ru, Rh and alloys thereof.

17. The magnetic recording medium according to claim 1, wherein the magnetic recording layer is a sputtered polycrystalline film.

18. The magnetic recording medium according to claim 1, wherein the magnetic recording layer includes cobalt and platinum.

19. The magnetic recording medium according to claim 1, wherein the magnetic recording layer is an alloy of two or more elements selected from the group consisting of Co, Cr, Pt, B, Ta, Pd, Sm, Fe and Ni.

20. The magnetic recording medium according to claim 1, wherein the magnetic recording layer comprises an oxide based grain boundary to separate the grains, and the oxide based grain boundary is obtained from one or more elements selected from the group consisting of Si, Cr, Ta, Ti, Al and Mg.

21. The magnetic recording medium according to claim 1, further comprising a protective layer above the magnetic recording layer, wherein the protective layer coats the magnetic recording layer to prevent corrosion and comprises a material selected from the group consisting of carbon, nitrogenated carbon, hydrogenated carbon and silicon nitride.

22. The magnetic recording medium according to claim 1, wherein the magnetic recording medium is a disk and provides perpendicular magnetic recording for a disk drive.

23. A method of making a magnetic recording medium, comprising:
providing a base structure;
depositing an Iridium-Manganese based intermediate layer over the base structure at a sputtering gas pressure higher than that is used for depositing a layer below the Iridium-Manganese based intermediate layer, wherein the Iridium-Manganese based intermediate layer is primarily IrₓMn₁₋ₓ, wherein x, which is the atomic component of Iridium in the alloy, is between 15-40%; and
sputtering a magnetic recording layer over the Iridium-Manganese based intermediate layer.

24. The method according to claim 23, wherein the Iridium-Manganese based intermediate layer comprises a material selected from the group consisting of Cr, Ti, Ta, Pt, Pd, Ru, Rh, Re, Fe, Co, Ni, Zr, Ag, Au, In, Cu, Al, Mo, Nb, Mg and alloys thereof.

25. The method according to claim 23, wherein the Iridium-Manganese based intermediate layer comprises a gas selected from the group consisting of hydrogen gas, nitrogen gas and oxygen gas.

26. The method according to claim 23, wherein the Iridium-Manganese based intermediate layer includes a metal selected from the group consisting of Pt, Pd, Cr, Fe, Ni, Co, Ru, Rh and alloys thereof.

27. The method according to claim 23, wherein the Iridium-Manganese based intermediate layer is sputtered in the presence of a reactive gas selected from the group consisting of oxygen, nitrogen and hydrogen.

28. The method according to claim 23, wherein the Iridium-Manganese based intermediate layer is an upper intermediate layer, a lower intermediate layer is sandwiched between the Iridium-Manganese based upper intermediate layer and the base structure, and the Iridium-Manganese based upper intermediate layer is sputtered at a higher sputter gas pressure than the lower intermediate layer it is disposed on.

29. The method according to claim 28, wherein the lower intermediate layer comprises ruthenium.

30. The method according to claim 28, wherein the lower intermediate layer is selected from the group consisting of Ru, Cr, Cu, Co, Ti, Zr, Ag, Au, Al, Mg, Mn, Pt, Pd, Ta, Nb, Mo, Re and alloys thereof.

31. The method according to claim 23, wherein at least one other intermediate layer is sandwiched between the Iridium-Manganese based intermediate layer and the magnetic recording layer for controlling the crystallographic and morphological properties of the magnetic recording layer.
